(19) United States
(12) Patent Application Publication
(10) Pub. No.: US 2026/0182126 A1
(43) Pub. Date: Jun. 25, 2026

(54) LIGHT EMITTING DISPLAY DEVICE

(71) Applicant: LG Display Co., Ltd., Seoul (KR)

(72) Inventors: Min-Ki KIM, Paju-si (KR); Hoon-Sok SON, Paju-si (KR); Hak-Min LEE, Paju-si (KR); Beom-Gon JO, Paju-si (KR)

(73) Assignee: LG Display Co., Ltd., Seoul (KR)

(21) Appl. No.: 19/356,961

(22) Filed: Oct. 13, 2025

(30) Foreign Application Priority Data
Dec. 24, 2024 (KR) 10-2024-0195954

(51) Int. Cl. H10H 29/853; H10H 29/34; H10H 29/85

(52) U.S. Cl. CPC H10H 29/853; H10H 29/34; H10H 29/8517

(57) ABSTRACT

A light emitting display device includes: a substrate including a plurality of subpixels including a red subpixel, a green subpixel, and a blue subpixel, wherein each of the red, green, and blue subpixels has a light emitting diode including a first electrode, a light emitting layer, and a second electrode that are stacked; a first semi-transparent plate, a second semi-transparent plate, and a third semi-transparent plate placed on the light emitting diodes of the blue, green, and red subpixels, respectively; a first insulating layer covering the first semi-transparent plate and placed below the second and third semi-transparent plates; and a second insulating layer covering the first and second semi-transparent plates and placed below the third semi-transparent plate.

### CROSS REFERENCE TO RELATED APPLICATION

The present application claims the priority benefit of Korean Patent Application No. 10-2024-0195954, filed in the Republic of Korea on December 24, 2024, which is hereby incorporated by reference in its entirety for all purposes as if fully set forth herein.

### BACKGROUND

### Field of the Disclosure

The present disclosure relates to a light emitting display device.

### Discussion of the Related Art

Recently, flat panel display devices with excellent characteristics, such as thinness, weight reduction, and low power consumption, have been widely developed and applied to various fields.

Among the flat panel display devices, light emitting display devices equipped with light emitting elements, such as light emitting diodes, are display devices that emit light when charges are injected into a light emitting layer formed between an anode and a cathode, and electrons and holes are paired and then extinguished.

Recently, in the light emitting display device, a subpixel can be configured with a micro cavity structure to improve emission efficiency of a corresponding color. However, processes for forming the micro cavity structures are complex and difficult and increase process cost.

### SUMMARY

An advantage of the present disclosure is to provide a light emitting display device that can more easily implement a micro cavity structure and reduce process cost.

Additional features and advantages of the present disclosure will be set forth in the description which follows, and in part will be apparent from the description, or may be learned by practice of the disclosure. These and other advantages of the present disclosure will be realized and attained by the structure particularly pointed out in the written description and claims hereof as well as the appended drawings.

To achieve these and other advantages and in accordance with the purpose of the present disclosure, as embodied and broadly described herein, a light emitting display device includes: a substrate including a plurality of subpixels including a red subpixel, a green subpixel, and a blue subpixel, wherein each of the red, green, and blue subpixels has a light emitting diode including a first electrode, a light emitting layer, and a second electrode that are stacked; a first semi-transparent plate, a second semi-transparent plate, and a third semi-transparent plate placed on the light emitting diodes of the blue, green, and red subpixels, respectively; a first insulating layer covering the first semi-transparent plate and placed below the second and third semi-transparent plates; and a second insulating layer covering the first and second semi-transparent plates and placed below the third semi-transparent plate.

It is to be understood that both the foregoing general description and the following detailed description are by way of example and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this specification, illustrate example embodiments of the disclosure and together with the description serve to explain various principles of the disclosure. In the drawings:

FIG. 1 is a plan view schematically illustrating a light emitting display device according to a first example embodiment of the present disclosure;

FIG. 2 is a cross-sectional view taken along a line II-II’ in FIG. 1;

FIGS. 3 to 7 are views illustrating a method of manufacturing a light emitting display device according to a first example embodiment of the present disclosure; and

FIG. 8 is a cross-sectional view schematically illustrating a light emitting display device according to a second example embodiment of the present disclosure.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms. The present disclosure is provided to fully inform the scope of the disclosure to those skilled in the art of the present disclosure, and the protected scope of the present disclosure may be defined by the scope of the claims and their equivalents.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, where a detailed description of the related known technology may unnecessarily obscure the subject matter of the present disclosure, the detailed description thereof can be omitted. Where such terms as ‘comprising’, ‘including’, ‘having’, ‘consisting’, and the like are used in this specification, other parts can be added unless a more specific term like ‘only’ is used. Where a component is expressed in the singular, cases including the plural are included unless specific statement is described.

In interpreting the components, even if there is no separate explicit description, they are to be interpreted as including a margin range.

In the case of a description of a positional relationship, for example, where the positional relationship of two parts is described as ‘on’, ‘over’, ‘above’, ‘below’, ‘beside’, ‘under’, and the like, one or more other parts can be positioned between such two parts unless a more specific term like ‘right’ or ‘directly’ is used.

In the case of a description of a temporal relationship, for example, where a temporal precedence is described as ‘after’, ‘following’, ‘before’, and the like, cases that are not continuous can be included unless a more specific term like ‘directly’ or ‘immediately’ is used.

In describing components of the present disclosure, terms such as first, second and the like can be used. These terms are only for referring to the components separately from other components, and an essence, order, order, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with an associated relationship.

Hereinafter, example embodiments of the present disclosure are described in detail with reference to the drawings. In the following embodiments, the same and like reference numerals are assigned to the same and like components, and detailed descriptions thereof may be omitted.

### First Embodiment

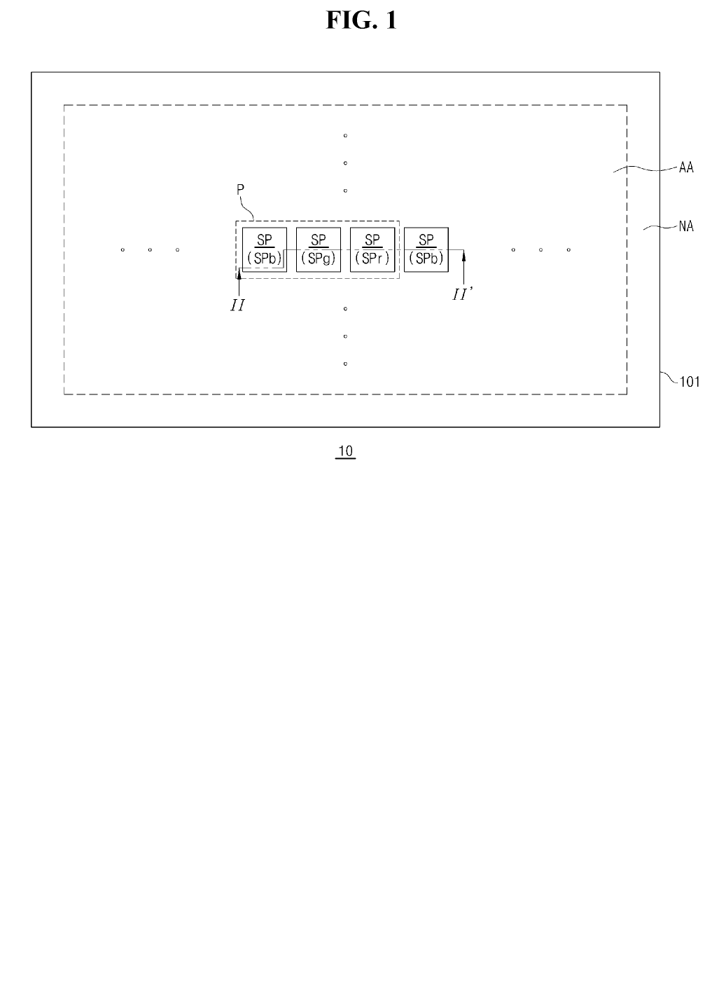

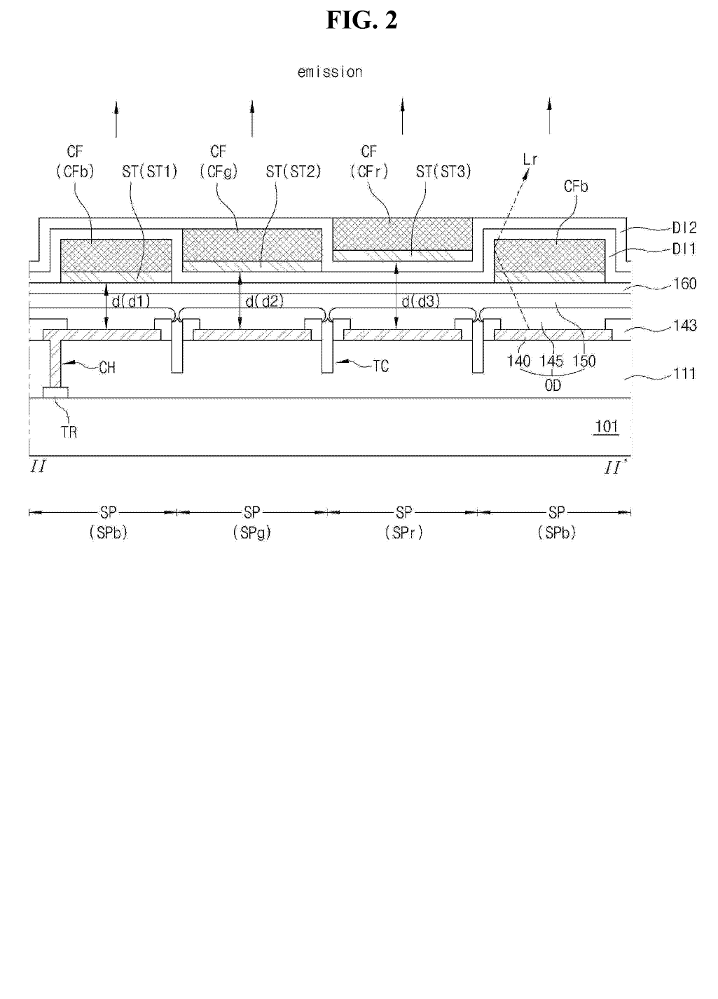

FIG. 1 is a plan view schematically illustrating a light emitting display device according to a first example embodiment of the present disclosure. FIG. 2 is a cross-sectional view taken along a line II-II’ in FIG. 1, schematically illustrating a cross-sectional structure of example subpixels.

Prior to a detailed description, the light emitting display device 10 according to the first example embodiment of the present disclosure can include any type of display device that displays images using a light emitting diode OD which is a self-luminous element.

In this example embodiment, for convenience of explanation, an organic light emitting display device can be used as the light emitting display device 10.

The light emitting display device 10 can be a top emission type or bottom emission type display device. In this example embodiment, for convenience of explanation, a top emission type light emitting display device 10 can be used as an example.

As shown in FIG. 1, the light emitting display device 10 (or its light emitting display panel) of this example embodiment can include a display region AA for displaying an image and a non-display region NA arranged around the display region AA. The display region AA can include a plurality of subpixels SP arranged along a plurality of row lines (or horizontal lines) and a plurality of column lines (or vertical lines) on a substrate 101.

Meanwhile, although not specifically illustrated, a plurality of gate lines (or scan lines) extending along the row direction (or horizontal direction or first direction) and a plurality of data lines extending along the column direction (or vertical direction or second direction) can be formed on the substrate 101. Each subpixel SP can be connected to corresponding gate line and data line.

Furthermore, a power line transmitting a high-potential driving voltage and a power line transmitting a low-potential driving voltage can be formed on the substrate 101. The high-potential driving voltage and the low-potential driving voltage can be applied to the subpixel SP.

The plurality of subpixels SP formed on the substrate 101 can include subpixels SP of different colors that constitute a pixel P which is a unit for displaying a color image. For example, the subpixels SP constituting the pixel P can include subpixels SP that display first, second, and third colors, respectively, for example, blue, green, and red subpixels SPb, SPg, and SPr that display blue, green, and red, respectively. As another example, the subpixels SP constituting the pixel P can further include a white subpixel that displays white.

In this embodiment, the case where the pixel P is configured with the red, green, and blue subpixels SPr, SPg, and SPb is taken as an example.

The red, green, and blue subpixels SPr, SPg, and SPb can be arranged in various configurations. For example, as illustrated in FIG. 1, the subpixels SP can be arranged in a stripe type, with subpixels SP of the same color arranged in a stripe configuration in which subpixels (SP) of the same color are arranged in the column direction and subpixels SP of different colors are alternately arranged in the row direction, but the present disclosure is not limited thereto.

Each subpixel SP can include the light emitting diode OD which is a light emitting element. Furthermore, the subpixel SP can include a pixel driving circuit that drives the light emitting diode OD. The pixel driving circuit can include a plurality of thin film transistors TR including a driving transistor, and at least one capacitor. In this case, during an emission period, the driving transistor can be turned on to generate an emission current, and the emission current can be provided to the light emitting diode OD to perform an emission operation.

Each subpixel SP can be implemented with a micro cavity structure to increase emission efficiency of its corresponding color, and the micro cavity structure can be configured with a semi-transparent laminated film and a reflective laminated film that are arranged vertically with a light emitting layer 145 interposed therebetween.

In this regard, for example, the red subpixel SPr, the green subpixel SPg, and the blue subpixel SPb can emit light of different colors, i.e., different wavelengths, and thus they can have different cavity thicknesses, i.e., resonant distances (d: d1, d2, and d3).

In this regard, the red, green, and blue subpixels SPr, SPg, and SPb can have the resonant distances d proportional to their color wavelengths (or half-wavelengths). The resonant distance d of each subpixel SP can be matched to an integer multiple of the half-wavelength of its corresponding color.

In this regard, the red subpixel SPr, which outputs a color of the longest wavelength, can have a relatively largest third resonant distance d3. The green subpixel SPg, which outputs a color of the middle wavelength, can have a second resonant distance d2 smaller than the third resonant distance d3. The blue subpixel SPb, which outputs a color of the shortest wavelength, can have a first resonant distance d1 smaller than the second resonant distance d2.

As such, by utilizing the micro cavity structure, color purity and emission efficiency can be improved.

In this embodiment, in implementing the resonant distances d of the subpixels SP of different colors, semi-transparent plates (or semi-transparent electrodes) ST, which are laminated films having semi-transparent characteristics and positioned on an upper side in an upper direction that is an emitting direction of the micro cavity structure, can be substantially placed on the light emitting diodes OD. In addition, positions (or heights) at which the semi-transparent plates ST are placed can be differentiated according to the subpixels SP, thereby implementing the resonant distances d of the subpixels SP.

In addition, in each subpixel SP, a corresponding color filter pattern CF can be stacked on the semi-transparent plate ST.

As such, in this embodiment, in implementing the microcavity structure, the semi-transparent plate ST can be placed on the light emitting diode OD to set the resonant distance d. Accordingly, the micro cavity structure can be formed through simple, low-difficulty processes, thereby reducing cost.

The configuration and implementation method of the micro cavity structure of this embodiment can be described in more detail below.

The cross-sectional structure of the subpixel SP having the micro cavity structure can be described with reference to FIG. 2.

The substrate 101 of the light emitting display device 10 can be an insulating substrate, such as a glass substrate or a plastic substrate. Alternatively, the substrate 101 can be a silicon substrate (or silicon wafer) formed of crystalline silicon (e.g., single crystal silicon) that functions as a semiconductor, and in this case, there is an advantage of effectively implementing a small-sized display device with high resolution.

In this example embodiment, for convenience of explanation, an insulating substrate is used as an example, but the present disclosure is not limited thereto.

A plurality of thin film transistors TR can be formed in each subpixel SP on the substrate 101. Meanwhile, in this example embodiment, for convenience of explanation, in FIG. 2, one thin film transistor TR connected to the light emitting diode OD is illustrated in the left blue subpixel SPb, but the present disclosure is not limited thereto. The thin film transistor TR can be an emission control transistor or a driving transistor, but is not limited thereto.

Although not specifically illustrated, the thin film transistor TR can include a semiconductor layer, a gate insulating film, a gate electrode, a source electrode, and a drain electrode. Here, the thin film transistor TR can be a thin film transistor of a bottom-gate structure in which the gate electrode is positioned below the semiconductor layer, or be a thin film transistor of a top-gate structure in which the gate electrode is positioned over the semiconductor layer.

Meanwhile, in a case where a semiconductor substrate is used as the substrate 101, an active region functioning as a semiconductor layer can be formed within the semiconductor substrate.

A passivation layer 111 can be formed on the thin film transistor TR. The passivation layer 111 can be formed in a single-layered structure or a multi-layered structure. The passivation layer 111 can be formed of an organic insulating material and/or an inorganic insulating material.

The passivation layer 111 can be formed substantially over the entire surface of the substrate 101 while covering the thin film transistor TR. The passivation layer 111 can have a flat upper surface, but not limited thereto. For example, at least an upper portion of the passivation layer 111 can be formed of a planarization layer.

Meanwhile, a contact hole CH exposing one electrode of the thin film transistor TR, for example, a drain electrode, can be formed in the passivation layer 111.

On the substrate 101 on which the passivation layer 111 is formed, a first electrode (or anode) 140 of the light emitting diode OD can be formed for each subpixel SP. The first electrode 140 can be formed in a patterned form for each subpixel SP.

The first electrode 140 can include, for example, a reflective layer (or reflective plate or reflective electrode) made of a highly reflective metal. The reflective layer can be formed of, for example, at least one of silver (Ag), aluminum (Al), molybdenum (Mo), titanium (Ti), and an APC (Al-Pd-Cu) alloy, but not limited thereto.

The reflective layer of the first electrode 140, together with the semi-transparent plate ST positioned thereon, can implement a micro cavity structure of the corresponding subpixel SP.

Furthermore, the first electrode 140 can include a transparent conductive layer (or transparent electrode) laminated together with the reflective layer. The transparent conductive layer can be formed of, for example, a transparent conductive material such as indium tin oxide (ITO), indium zinc oxide (IZO), or nitride zinc oxide (ITZO), but not limited thereto.

The first electrode 140 formed in each subpixel SP can be connected to the drain electrode of the thin film transistor TR of the corresponding subpixel SP through the contact hole CH.

A bank (or partition wall or fence) 143 positioned along an edge of each subpixel SP and surrounding the subpixel SP can be formed on the first electrode 140. The bank 143 can be made of an inorganic insulating material or an organic insulating material.

The bank 143 can have an opening that exposes the first electrode 140 of each subpixel SP and can be configured to cover an edge of the first electrode 140. By the opening of the bank 143, an emission region (or light emitting diode OD) where light is actually generated within the subpixel SP can be defined.

A trench TC can be formed in the bank 143 and the passivation layer 111 below the bank 143. For example, the trench TC can be formed along a boundary between the subpixels SP of different colors in the column direction. Alternatively, a trench TC can also be formed along a boundary between the subpixels SP of the same color in the row direction.

By forming the trench TC, lateral leakage current between adjacent subpixels SP can be prevented or suppressed.

The light emitting layer 145 can be formed on the bank 143 and on the first electrode 140 exposed through the opening of the bank 143. The light emitting layer 145 can be formed substantially over the entire substrate 101 (or the entire display region AA).

The light emitting layer 145 can be, for example, an organic light emitting layer formed using an organic material. The light emitting layer 145 can be formed with a multi-layered structure including an emitting material layer that actually emits light.

The light emitting layer 145 (or at least a portion of the light emitting layer 145) can be separated (or disconnected or divided) by the trench TC formed in the bank 143 and the passivation layer 111.

The light emitting layer 145 can be formed with a single-layered stack structure or a multi-layered stack structure.

When the light emitting layer 145 is formed with a single-layered stack structure, the light emitting layer 145 can be separated by the trench TC.

Meanwhile, when the light emitting layer 145 is configured with a multi-layered stack structure, a charge generation layer can be provided between adjacent stacks. In this case, for example, a lower stack and the charge generation layer on the lower stack can be separated by the trench TC, and an upper stack can be configured such that at least an upper portion of the upper stack is not separated over the trench TC and is connected over the trench TC.

The light emitting layer 145 can be configured as, for example, a white light emitting layer that emits white light. Accordingly, the light emitting diodes OD of all subpixels SP can emit the same white light.

A second electrode (or cathode) 150 can be formed on the light emitting layer 145 and substantially over the entire surface of the substrate 101.

In this regard, the second electrode 150 can be formed continuously between adjacent subpixels SP without being separated by the trench TC. Accordingly, the second electrode 150 can be formed continuously along all subpixels SP of the display region AA.

The second electrode 150 can be formed of a transparent electrode having transmissive characteristics. The second electrode 150 can be formed of a transparent conductive material such as ITO, IZO, or ITZO, but not limited thereto.

The first electrode 140, the light emitting layer 145, and the second electrode 150, stacked as described above, can form the light emitting diode OD. Accordingly, the light emitting diode OD can be formed in each subpixel SP.

As mentioned above, the light emitting diode OD can be configured to include the light emitting layer 145 that emits white light, and thus can serve as a white light emitting diode.

Meanwhile, in the display region AA, the same laminated structure can be formed below the light emitting diodes OD. In other words, in substantially all subpixels SP, the same laminated structure can be formed below the light emitting diodes OD.

Accordingly, in all subpixels SP, the light emitting diode OD and the laminated structure therebelow can be formed substantially identically.

Therefore, processes up to forming the light emitting diode OD on the substrate 101 can be performed simply and without complexity.

Furthermore, since the subpixels SP can have the light emitting diodes OD with substantially identical structures, uniformity in emission characteristics can be ensured among the subpixels SP.

On the substrate 101 where the light emitting diode OD is formed, the semi-transparent plate ST, which implements the micro cavity structure along with the first electrode 140 with reflective characteristics, can be formed by subpixel SP.

In this regard, for example, an insulating layer 160 can be formed on the light emitting diode OD. The insulating layer 160 can be formed substantially over the entire surface of the substrate 101. Meanwhile, in some cases, the insulating layer 160 on the light emitting diode OD can be omitted. In this embodiment, an example is given in which the insulating layer 160 is formed on the light emitting diodes OD of the subpixels SP.

The insulating layer 160 can be formed of, for example, an inorganic insulating material and/or an organic insulating material. Furthermore, the insulating layer 160 can have, for example, relatively low refractive characteristics. The insulating layer 160 can be formed with a single-layered or multi-layered structure, including, for example, at least one of Al2O3, SiO2, SiNx, a monomer, and polyimide, but not limited thereto.

On the insulating layer 160, for example, a first semi-transparent plate ST1 and a blue color filter pattern (or first color filter pattern) (CF:CFb) thereon can be formed corresponding to the blue subpixel SPb.

As such, in the blue subpixel SPb, the first semi-transparent plate ST1 can be disposed on the light emitting diode OD. Here, the first semi-transparent plate ST1 can be located at a position (or height) spaced apart from the first electrode 140, which functions as a reflective plate, by a first resonant distance d1 for emission of blue light.

Accordingly, in the blue subpixel SPb, the micro cavity structure configured with the first electrode 140 functioning as a reflective plate and the first semi-transparent plate ST1 can be implemented.

Thus, in the blue subpixel SPb, white light generated from the light emitting diode OD can be reflected between the first electrode 140 and the first semi-transparent plate ST1 of the micro cavity structure, thereby generating blue light and outputting it upward.

The first semi-transparent plate ST1 can be formed of, for example, a metal that has semi-transparent characteristics, such as Mg, Ag, or an alloy of Mg and Ag (Mg:Ag), but not limited thereto.

The blue color filter pattern CFb laminated on the first semi-transparent plate ST1 can filter the blue light output through the first semi-transparent plate ST1 and output it to the outside. As such, by directly disposing the blue color filter pattern CFb on the first semi-transparent plate ST1, color purity can be improved.

On the substrate 101 where the blue color filter pattern CFb is formed, for example, a first insulating layer (or first dielectric layer) DI1 can be formed entirely over the substrate 101.

For example, the first insulating layer DI1 can be formed along the surface of the substrate 101 where the blue color filter pattern CFb is formed, covering the surface of the substrate 101.

In this case, the first insulating layer DI1 can enclose (or cover) upper and side surfaces of a stack of the first semi-transparent plate ST1 and the blue color filter pattern CFb.

Furthermore, the first insulating layer DI1 can cover a portion of the insulating layer 160 which is exposed in an interval region between the stacks, each of which is configured with the first semi-transparent plate ST1 and the blue color filter pattern CFb. In other words, the first insulating layer DI1 can cover the portion of the insulating layer 160 in a region of the green and red subpixels SPg and SPr.

The first insulating layer DI1 can be formed of, for example, an inorganic insulating material and/or an organic insulating material, similar to the insulating layer 160 below the first insulating layer DI1. In addition, the first insulating layer DI1 can have, for example, a relatively low refractive characteristics, similar to the insulating layer 160 therebelow. The first insulating layer DI1 can be formed of the same material as the insulating layer 160, and can be formed in a single-layered or multi-layered structure, including, for example, at least one of Al2O3, SiO2, SiNx, a monomer, and polyimide, but not limited thereto.

Here, the first insulating layer DI1 can be formed, for example, with a thickness that is the same as or different from that of the insulating layer 160 thereblow.

On the first insulating layer DI1, for example, a second semi-transparent plate ST2 and a green color filter pattern (or second color filter pattern) (CF:CFg) thereon can be formed corresponding to the green subpixel SPg.

As such, in the green subpixel SPg, the second semi-transparent plate ST2 can be disposed on the light emitting diode OD. Here, the second semi-transparent plate ST2 can be located at a position (or height) spaced apart from the first electrode 140, which functions as a reflective plate, by a second resonant distance d2 for emission of green light.

In this regard, the first insulating layer DI1 can be formed below the second semi-transparent plate ST2, so that the second semi-transparent plate ST2 can be positioned higher than the first semi-transparent plate ST1 by a thickness of the first insulating layer DI1. The thickness of the first insulating layer DI1 can be set such that the second resonant distance d2 can be secured, and thus the second semi-transparent plate ST2 can be spaced apart from the first electrode 140 by the second resonant distance d2.

As such, by forming the first insulating layer DI1 below the second semi-transparent plate ST2, the second resonant distance d2 for emission of green light can be optimally set.

Accordingly, in the green subpixel SPg, the micro cavity structure configured with the first electrode 140 functioning as a reflective plate and the second semi-transparent plate ST2 can be implemented.

Thus, in the green subpixel SPg, white light generated from the light emitting diode OD can be reflected between the first electrode 140 and the second semi-transparent plate ST2 of the microcavity structure, thereby generating green light and outputting it upward.

The second semi-transparent plate ST2 can be formed of, for example, the same material as the first semi-transparent plate ST1, which is a metal such as Mg, Ag, or an alloy of Mg and Ag (Mg:Ag), but not limited thereto.

The green color filter pattern CFg laminated on the second semi-transparent plate ST2 can filter the green light output through the second semi-transparent plate ST2 and output it to the outside. As such, by directly disposing the green color filter pattern CFg on the second semi-transparent plate ST2, color purity can be improved.

Meanwhile, the second semi-transparent plate ST2 and the green color filter pattern CFg can be formed after the first insulating layer DI1 is formed, so that, in a lateral direction, the first insulating layer DI1 can be interposed like a sidewall between the second semi-transparent plate ST2 and the green color filter pattern CFg, and the first semi-transparent plate ST1 and the blue color filter pattern CFb. In other words, the first insulating layer DI1 can be interposed between the blue subpixel SPb and its adjacent green subpixel SPg, so that the first semi-transparent plate ST1 and the blue color filter pattern CFb can be physically separated from the second semi-transparent plate ST2 and the green color filter pattern CFg.

On the substrate 101 where the green color filter pattern CFg is formed, for example, a second insulating layer (or second dielectric layer) DI2 can be formed entirely over the substrate 101.

For example, the second insulating layer DI2 can be formed along the surface of the substrate 101 where the green color filter pattern CFg is formed, covering the surface of the substrate 101.

In this case, the second insulating layer DI2 can cover an upper surface and one side surface of the first insulating layer DI1 that covers the first semi-transparent plate ST1 and the blue color filter pattern CFb. Furthermore, the second insulating layer DI2 can cover an upper surface and one side surface of a stack of the second semi-transparent plate ST2 and the green color filter pattern CFg. As such, the second insulating layer DI2 can enclose the first insulating layer DI1 covering the first semi-transparent plate ST1 and the blue color filter pattern CFb, and the stack of the second semi-transparent plate ST2 and the green color filter pattern CFg.

Furthermore, the second insulating layer DI2 can cover a portion of the first insulating layer DI1 which is exposed in an interval region between combinations, each of which is configured with the first insulating layer DI1 covering the first semi-transparent plate ST1 and the blue color filter pattern CFb, and the stack of the second semi-transparent plate ST2 and the green color filter pattern CFg. In this case, the second insulating layer DI2 can cover the portion of the first insulating layer DI1 in a region of the red subpixel SPr.

The second insulating layer DI2 can be formed of, for example, an inorganic insulating material and/or an organic insulating material, similar to the insulating layer 160 and the first insulating layer DI1 below the second insulating layer DI2. In addition, the second insulating layer DI2 can have, for example, relatively low refractive characteristics, similar to the insulating layer 160 and the first insulating layer DI1 therebelow. The second insulating layer DI2 can be formed of the same material as the insulating layer 160 and the first insulating layer DI1. For example, the second insulating layer DI2 can be formed of a single-layered or multi-layered structure, including at least one of Al2O3, SiO2, SiNx, a monomer, and polyimide, but not limited thereto.

Here, the second insulating layer DI2 can be formed, for example, with the same thickness as the first insulating layer DI1, but is not limited thereto.

On the second insulating layer DI2, for example, a third semi-transparent plate ST3 and a red color filter pattern (or third color filter pattern) (CF:CFr) thereon can be formed corresponding to the red subpixel SPr.

As such, in the red subpixel SPr, the third semi-transparent plate ST3 can be disposed on the light emitting diode OD. Here, the third semi-transparent plate ST3 can be located at a position (or height) spaced apart from the first electrode 140, which functions as a reflective plate, by a third resonant distance d3 for emission of red light.

In this regard, the first and second insulating layers DI1 and DI2 can be formed below the third semi-transparent plate ST3, so that the third semi-transparent plate ST3 can be positioned higher than the first semi-transparent plate ST1 by the thickness of the first and second insulating layers DI1 and DI2. In addition, the third semi-transparent plate ST3 can be positioned higher than the second semi-transparent plate ST2 by the thickness of the second insulating layer DI2.

The thickness of the second insulating layer DI2 and the thickness of the first insulating layer DI1 can be set such that the third resonant distance d3 can be secured, and thus the third semi-transparent plate ST3 can be spaced apart from the first electrode 140 by the third resonant distance d3.

As such, by forming the first and second insulating layers DI1 and DI2 below the third semi-transparent plate ST3, the third resonant distance d3 for emission of red light can be optimally set.

Accordingly, in the red subpixel SPr, the micro cavity structure configured with the first electrode 140 functioning as a reflective plate and the third semi-transparent plate ST3 can be implemented.

Thus, in the red subpixel SPr, white light generated from the light emitting diode OD can be reflected between the first electrode 140 and the third semi-transparent plate ST3 of the micro cavity structure, thereby generating red light and outputting it upward.

This third semi-transparent plate ST3 can be formed of, for example, the same material as the first and second semi-transparent plates ST1 and ST2, which is a metal such as Mg, Ag, or an alloy of Mg and Ag (Mg:Ag), but is not limited thereto.

The red color filter pattern CFr laminated on the third semi-transparent plate ST3 can filter the red light output through the third semi-transparent plate ST3 and output it to the outside. As such, by directly disposing the red color filter pattern CFr on the third semi-transparent plate ST3, color purity can be improved.

Meanwhile, the third semi-transparent plate ST3 and the red color filter pattern CFr can be formed after the second insulating layer DI2 is formed, so that, in the lateral direction, the second insulating layer DI2 can be interposed like a sidewall between the third semi-transparent plate ST3 and the red color filter pattern CFr, and the second semi-transparent plate ST2 and the green color filter pattern CFg. In other words, the second insulating layer DI2 can be interposed between the green subpixel SPg and its adjacent red subpixel SPr, so that the second semi-transparent plate ST2 and the green color filter pattern CFg can be physically separated from the third semi-transparent plate ST3 and the red color filter pattern CFr.

In addition, in the lateral direction, the first and second insulating layers DI1 and DI2 can be interposed like a sidewall between the third semi-transparent plate ST3 and the red color filter pattern CFr, and the first semi-transparent plate ST1 and the blue color filter pattern CFb. In other words, the first and second insulating layers DI1, DI2 can be interposed between the red subpixel SPr and its adjacent blue subpixel SPb, so that the third semi-transparent plate ST3 and the red color filter pattern CFr can be physically separated from the first semi-transparent plate ST1 and the blue color filter pattern CFb.

As described above, in this embodiment, the positions of the semi-transparent plates ST can be differentiated and arranged on the light emitting diodes OD according to the subpixels SP, and thus the micro cavity structures for emission of the color light of the subpixels SP can be implemented, and by adjusting the thickness of the insulating layer(s) below the semi-transparent plate ST for each of the subpixels SP, the positions of the semi-transparent plates ST can be differentiated and the resonant distances can be optimized.

In this regard, in implementing the micro cavity structure, a case where positions of reflective plates are differentiated and arranged under the light emitting diodes OD, it is very difficult to secure resonant distances due to an etching process, etc., resulting in high process complexity and difficulty and increased process cost.

However, in this embodiment, in implementing the micro cavity structure, a method can be used in which, after forming the light emitting diodes OD, the positions of the semi-transparent plates ST are differentiated on the light emitting diodes OD according to the subpixels SP.

Accordingly, the light emitting diode OD and the laminated structure therebelow can be formed substantially identically among the subpixels SP, so that processes up to forming the light emitting diodes OD on the substrate 101 can be easily performed with significantly low complexity and difficulty.

In addition, in forming the semi-transparent plates ST by differentiating their positions on the light emitting diodes OD according to the subpixels SP, the insulating layers DI1 and DI2 can be formed between processes of forming the semi-transparent plates ST, and thus a number of the insulating layer(s) disposed below the semi-transparent plates ST according to the subpixels SP can be varied, and thus the thickness of the insulating layer(s) below the semi-transparent plates ST can be differentiated. The processes of implementing such the differentiated arrangement structure of the semi-transparent plates ST can be easily performed with very low complexity and difficulty.

Consequently, processes of manufacturing the light emitting display device 10 having the micro cavity structure in this embodiment can be easily performed with very low complexity and difficulty overall, and thus process cost can also be reduced.

Meanwhile, in this embodiment, as mentioned above, the first and second insulating layers DI1 and DI2 can have low refractive characteristics. For example, the first and second insulating layers DI1 and DI2 can have lower refractive indices than refractive indices of the semi-transparent plate ST and the color filter pattern CF with which they are in direct contact.

In this case, side surfaces of the first and/or second insulating layers DI1 and/or DI2, which are positioned at the boundaries between adjacent subpixels SP and function as partition walls, can function as total reflection surfaces. In other words, the first and/or second insulating layers DI1 and/or DI2 at the boundaries of the subpixels SP can have a low refractive index, while the semi-transparent plate ST and the color filter pattern CF within the subpixel SP in contact with the first and/or second insulating layers DI1 and/or DI2 can have high refractive indices, and thus a total reflection can occur at an interface between the first and/or second insulating layers DI1 and/or DI2, and the semi-transparent plate ST and the color filter pattern CF due to the difference in refractive index.

Accordingly, for example, as illustrated in FIG. 2, color light Lr generated from the subpixel SP and incident on the first and/or second insulating layers DI1 and/or DI2 located at the boundary of the subpixel SP can be reflected and output upward.

Therefore, color mixing between adjacent subpixels SP can be prevented or suppressed, and light output efficiency to the front can be increased.

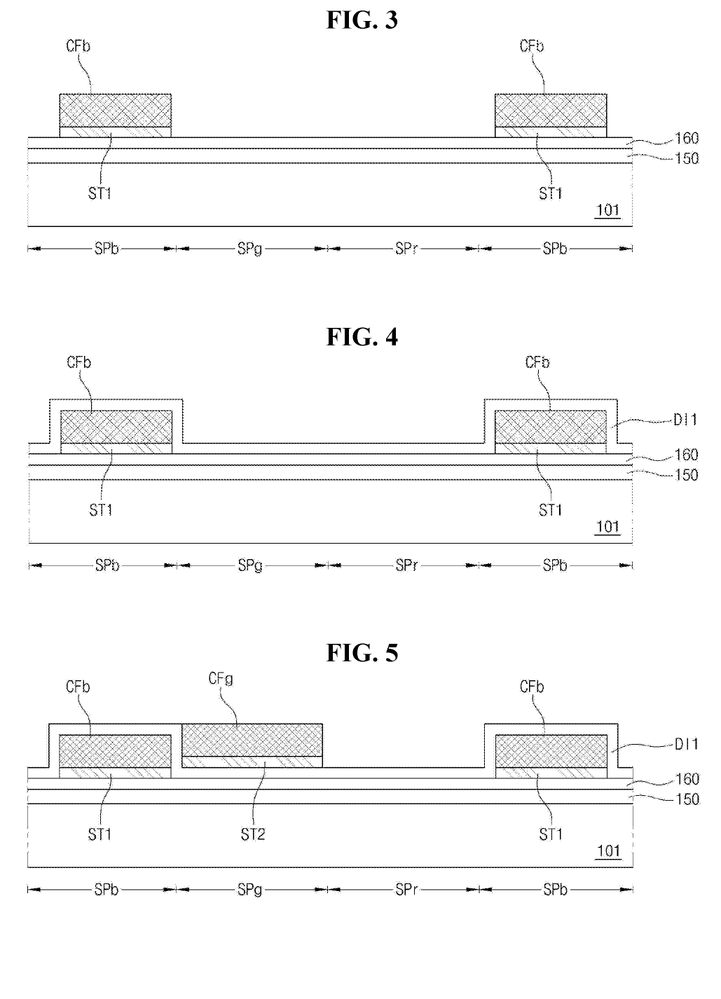

Hereinafter, a method of manufacturing the light emitting display device 10 according to this example embodiment can be described with further reference to FIGS. 3 to 7.

FIGS. 3 to 7 are views illustrating a method of manufacturing a light emitting display device according to a first example embodiment of the present disclosure. For convenience of explanation, in FIGS. 3 to 7, laminated layers below the second electrode 150 are omitted.

First, as shown in FIG. 3, the insulating layer 160 can be formed on the second electrode 150. Here, the insulating layer 160 can be formed as a single-layered or multi-layered structure including, for example, at least one of Al2O3, SiO2, SiNx, monomer, and polyimide, but not limited thereto.

The insulating layer 160 can be formed, for example, by an atomic layer deposition (ALD) method, but not limited thereto. When formed by the ALD method, the thickness of the insulating layer 160 can be adjusted, for example, in units of 1 Å. In this case, the resonant distances (d: d1, d2, d3) of the respective subpixels SP can be finely adjusted.

Next, on the insulating layer 160, for example, the first semi-transparent plate ST1 and the blue color filter pattern CFb thereon can be formed corresponding to the blue subpixel SPb.

Here, the first semi-transparent plate ST1 can be set to be located at a position (or height) spaced apart from the first electrode 140, which functions as a reflective plate, by the first resonant distance d1 for emission of blue light.

The first semi-transparent plate ST1 can be formed of, for example, a metal that has semi-transparent characteristics. For example, the first semi-transparent plate ST1 can be formed of a metal, such as Mg, Ag, or an alloy of Mg and Ag (Mg:Ag), but not limited thereto.

Next, as shown in FIG. 4, for example, the first insulating layer DI1 can be formed on the substrate 101 where the blue color filter pattern CFb is formed.

For example, the first insulating layer DI1 can be formed along the surface of the substrate 101 where the blue color filter pattern CFb is formed, covering the surface of the substrate 101.

Similar to the insulating layer 160, the first insulating layer DI1 can be formed in a single-layered or multi-layered structure, including, for example, at least one of Al2O3, SiO2, SiNx, a monomer, or polyimide, but not limited thereto.

The first insulating layer DI1 can be formed, for example, by an atomic layer deposition (ALD) method, but not limited thereto. When formed by the ALD method, the thickness of the first insulating layer DI1 can be adjusted, for example, in units of 1 Å. In this case, the resonant distances (d:d2,d3) of the green and red subpixels SPg and SPr can be finely adjusted.

Next, as shown in FIG. 5, on the first insulating layer DI1, for example, the second semi-transparent plate ST2 and the green color filter pattern CFg thereon can be formed corresponding to the green subpixel SPg.

Here, as the first insulating layer DI1 is formed below the second semi-transparent plate ST2, the second semi-transparent plate ST2 can be set to be located at a position (or height) spaced apart from the first electrode 140, which functions as a reflective plate, by the second resonant distance d2 for emission of green light.

The second semi-transparent plate ST2 can be formed of, for example, a metal that has semi-transparent characteristics. For example, the second semi-transparent plate ST2 can be formed of a metal, such as Mg, Ag, or an alloy of Mg and Ag (Mg:Ag), but not limited thereto.

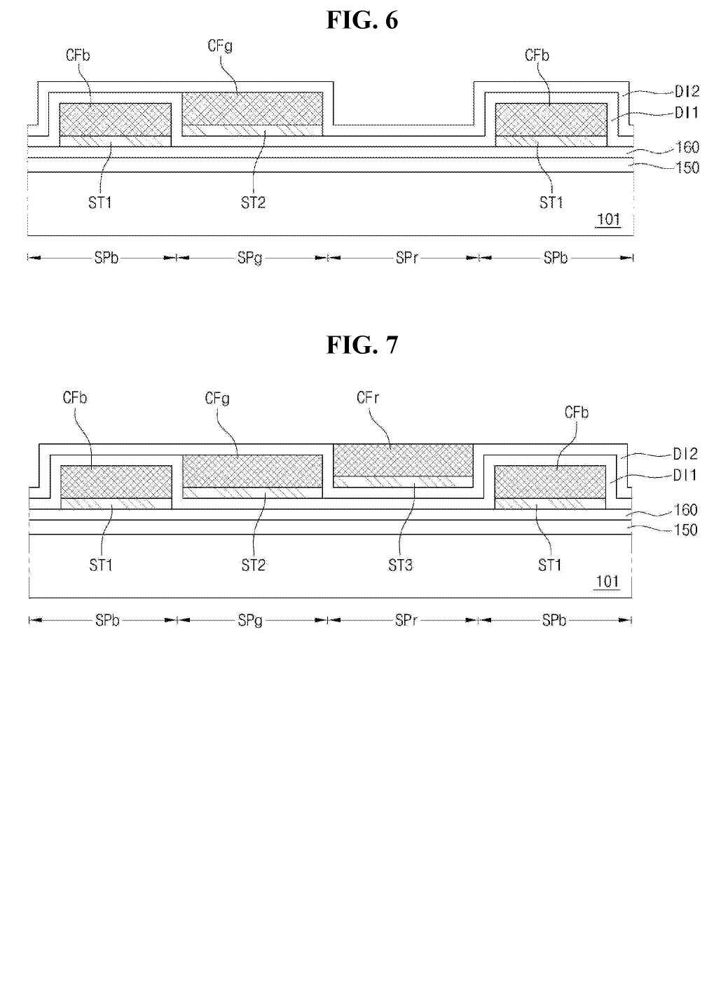

Next, as shown in FIG. 6, for example, the second insulating layer DI2 can be formed on the substrate 101 having the green color filter pattern CFg formed thereon.

For example, the second insulating layer DI2 can be formed along the surface of the substrate 101 having the green color filter pattern CFg formed thereon, covering the surface of the substrate 101.

Similar to the first insulating layer DI1, the second insulating layer DI2 can be formed in a single-layered or multi-layered structure, including, for example, at least one of Al2O3, SiO2, SiNx, a monomer, and polyimide, but not limited thereto.

The second insulating layer DI2 can be formed, for example, by using an atomic layer deposition (ALD) method, but not limited thereto. When formed using the ALD method, the thickness of the second insulating layer DI2 can be adjusted, for example, in units of 1 Å. In this case, the resonant distance (d:d3) of the red subpixel SPr can be finely adjusted.

Next, as shown in FIG. 7, on the second insulating layer (DI2), for example, the third semi-transparent plate ST3 and the red color filter pattern CFr thereon can be formed corresponding to the red subpixel SPr.

Here, as the first and second insulating layers DI1 and DI2 are formed below the third semi-transparent plate ST3, the third semi-transparent plate ST3 can be set to be located at a position (or height) spaced apart from the first electrode 140, which functions as a reflective plate, by the third resonant distance d3 for emission of red light.

The third semi-transparent plate ST3 can be formed of, for example, a metal that has semi-transparent characteristics. For example, the third semi-transparent plate ST3 can be formed of a metal, such as Mg, Ag, or an alloy of Mg and Ag (Mg:Ag), but is not limited thereto.

Through the above processes, the light emitting display device 10 in which the semi-transparent plates ST implementing the micro cavity structure are formed on the light emitting diodes OD can be manufactured.

In the light emitting display device 10 manufactured as described above, as mentioned above, the first, second, and third semi-transparent plates ST1, ST2, and ST3 can be placed on the light emitting diodes OD of the blue, green, and red subpixels SPb, SPg, and SPr, respectively. Here, the first insulating layer DI1 can cover the first semi-transparent plate ST1 and be positioned below the second and third semi-transparent plates ST2 and ST3, and the second insulating layer DI2 can cover the first and second semi-transparent plates ST1 and ST2 and be positioned below the third semi-transparent plate ST3.

In addition, in the green subpixel SPg, the first insulating layer DI1 can be positioned between the second semi-transparent plate ST2 and the light emitting diode OD, and in the red subpixel SPr, the second insulating layer DI2 can be positioned between the third semi-transparent plate ST3 and the first insulating layer DI1.

Furthermore, the insulating layer 160 can be formed between the light emitting diode OD and the first semi-transparent plate ST1, and the insulating layer 160 can be positioned along the red, green, and blue subpixels SPr, SPg, and SPb.

### Second Embodiment

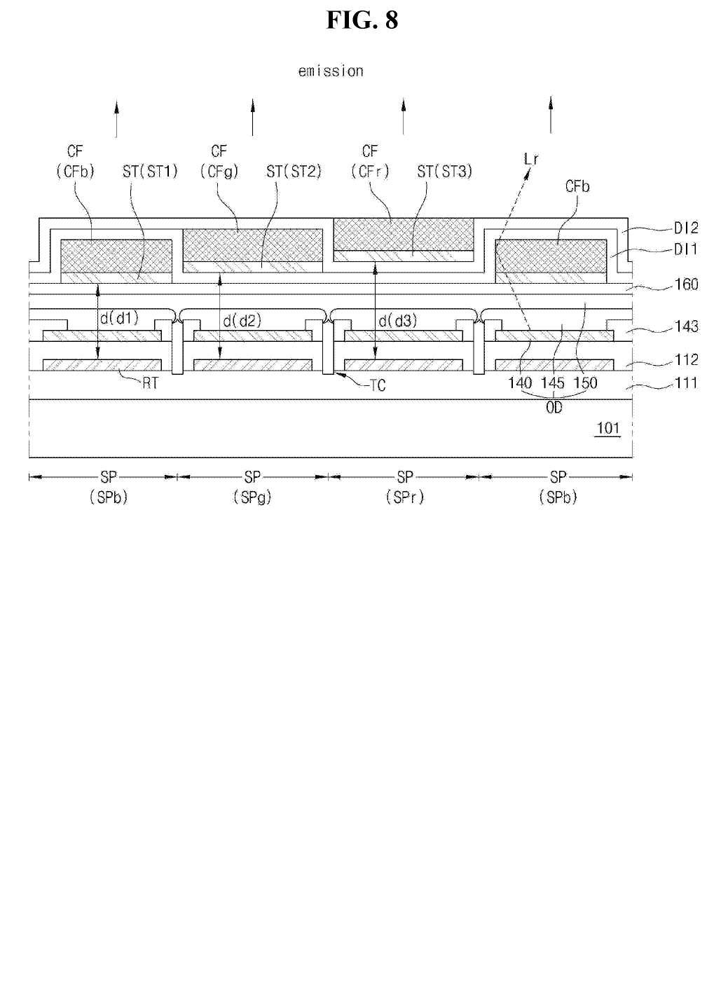

FIG. 8 is a cross-sectional view schematically illustrating a light emitting display device according to a second example embodiment of the present disclosure. In FIG. 8, for convenience of explanation, the thin film transistor (TR in FIG. 2) is omitted.

In the following description, detailed explanations of components identical to or similar to those of the first example embodiment described above can be omitted.

Similar to the first embodiment, the light emitting display device according to the second embodiment of the present disclosure can differentially arrange semi-transparent plates ST on light emitting diodes OD for respective subpixels SP to implement micro cavity structures for color emissions from the respective subpixels SP.

At this time, by adjusting the thickness of the insulating layer(s) below the semi-transparent plate ST for each of the subpixels SP, the positions of the semi-transparent plates ST can be differentiated and the resonant distances can be optimally set.

Meanwhile, in the light emitting display device of this example embodiment, a separate reflective plate RT forming a micro cavity along with the semi-transparent plate ST in each sub-pixel SP can be disposed below the light emitting diode OD.

In the first example embodiment described above, the first electrode 140 can be provided with a reflective layer having reflective characteristics, so that the first electrode 140 can function as a reflective plate.

However, in this example embodiment, the reflective plate RT can be formed below the first electrode 140, so that the micro cavity structure in each sub-pixel SP can be configured with the reflective plate RT and the semi-transparent plate ST which are located below and on the light emitting diode OD, respectively.

In this case, in the blue subpixel SPb, its corresponding reflective plate RT and the first semi-transparent plate ST1 can be arranged at a first resonant distance d1. In the green subpixel SPg, its corresponding reflective plate RT and the second semi-transparent plate ST2 can be arranged at a second resonant distance d2. In the red subpixel SPr, its corresponding reflective plate RT and the third semi-transparent plate ST3 can be arranged at a third resonant distance d3.

For example, regarding the micro cavity structure of this embodiment, the reflective plate RT can be formed on a first passivation layer 111, which is a passivation layer (111) on the substrate 101, for each subpixel SP. The reflective plate RT can be formed of a highly reflective metal, for example, but not limited to, at least one of Ag, Al, Mo, Ti, or an APC (Al-Pd-Cu) alloy.

The reflective plates RT can be placed at substantially the same height for all subpixels SP.

A second passivation layer 112 can be formed on the reflective plate RT substantially over the entire substrate 101. The second passivation layer 112 can be formed in a single-layered structure or a multi-layered structure. The second passivation layer 112 can be formed of an organic insulating material and/or an inorganic insulating material.

On the substrate 101 where the second passivation layer 112 is formed, a first electrode 140 of the light emitting diode OD can be formed for each subpixel SP. Alternatively, the second passivation layer 112 can be omitted, and in this case, the first electrode 140 can be formed on the substrate 101 where the reflective plate RT is formed.

Here, the first electrode 140 can be formed of a transparent conductive material and configured as a transparent electrode having transmissive characteristics. Accordingly, light generated from the light emitting layer 145 can pass through the first electrode 140 and be provided to the reflective plate RT below.

A bank 143 positioned along an edge of each subpixel SP and surrounding the subpixel SP can be formed on the first electrode 140.

The light emitting layer 145 can be formed on the bank 143 and the first electrode 140. At least a lower portion of the light emitting layer 145 can be separated by, for example, a trench TC formed in the bank 143 and the passivation layers 111 and 112.

A second electrode 150 can be formed on the light emitting layer 145 substantially over the entire substrate 101. The second electrode 150 can be configured as a transparent electrode having transmissive characteristics.

Similar to the first embodiment, on the light emitting diode OD configured as described above, the semi-transparent plate ST, which implements the micro cavity structure for each subpixel SP can be formed, and a color filter pattern CF can be laminated on the semi-transparent plate ST.

In this regard, in the blue subpixel SPb, a first semi-transparent plate ST1 and a blue color filter pattern CFb thereon can be formed.

On the substrate 101 where the blue color filter pattern CFb is formed, for example, a first insulating layer DI1 can be formed substantially over the entire substrate 101.

On the first insulating layer DI1, for example, a second semi-transparent plate ST2 and a green color filter pattern CFg thereon can be formed corresponding to the green subpixel SPg.

On the substrate 101 where the green color filter pattern CFg is formed, for example, a second insulating layer DI2 can be formed substantially over the entire substrate 101.

On the second insulating layer DI2, for example, a third semi-transparent plate ST3 and a red color filter pattern CFr thereon can be formed corresponding to the red subpixel SPr.

As described above, in this embodiment, the reflective plate RT can be formed below the light emitting diode OD by subpixel SP. Accordingly, the micro cavity structure in each subpixel SP can be configured with the reflective plate RT and the semi-transparent plate ST positioned below and on the light emitting diode OD, respectively.

Since the reflective plates RT can be formed at the same height in the same process among all subpixels SP, the reflective plates RT can be formed easily.

As described above, according to the embodiments of the present disclosure, in implementing the micro cavity structures for the respective subpixels, after forming the light emitting diodes, the positions of the semi-transparent plates can be differentiated among the subpixels, so that the micro cavity structures for emission of the color light of the subpixels SP can be implemented. At this time, by adjusting the thickness of the insulating layer(s) below the semi-transparent plate for each of the subpixels SP, the positions of the semi-transparent plates ST can be differentiated and the resonant distances can be optimally set.

Accordingly, the light emitting diode and the laminated structure therebelow can be formed substantially identically among the subpixels SP, so that processes up to forming the light emitting diodes OD on the substrate 101 can be easily performed with significantly low complexity and difficulty.

Furthermore, in forming the semi-transparent plates by differentiating their positions on the light emitting diodes according to the subpixels, the insulating layers can be formed between processes of forming the semi-transparent plates, and thus a number of the insulating layer(s) disposed below the semi-transparent plates according to the subpixels SP can be varied, and thus the thickness of the insulating layer(s) below the semi-transparent plates can be differentiated. The processes of implementing such the differentiated arrangement structure of the semi-transparent plates can be easily performed with very low complexity and difficulty.

Consequently, processes of manufacturing the light emitting display device having the micro cavity structure can be easily performed with very low complexity and difficulty overall, and thus process cost can also be reduced.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A light emitting display device, comprising:
a substrate including a plurality of subpixels including a red subpixel, a green subpixel, and a blue subpixel, wherein each of the red, green, and blue subpixels has a light emitting diode including a first electrode, a light emitting layer, and a second electrode that are stacked;
a first semi-transparent plate, a second semi-transparent plate, and a third semi-transparent plate placed on the light emitting diodes of the blue, green, and red subpixels, respectively;
a first insulating layer covering the first semi-transparent plate and placed below the second and third semi-transparent plates; and
a second insulating layer covering the first and second semi-transparent plates and placed below the third semi-transparent plate.

2. The light emitting display device of claim 1, wherein in the green subpixel, the first insulating layer is positioned between the second semi-transparent plate and the light emitting diode, and
wherein in the red subpixel, the second insulating layer is positioned between the third semi-transparent plate and the first insulating layer.

3. The light emitting display device of claim 1, wherein in a lateral direction, the first insulating layer is interposed between the first semi-transparent plate and the second semi-transparent plate,
wherein in the lateral direction, the second insulating layer is interposed between the second semi-transparent plate and the third semi-transparent plate, and
wherein in the lateral direction, the first and second insulating layers are interposed between the third semi-transparent plate and the first semi-transparent plate.

4. The light emitting display device of claim 1, wherein a blue color filter pattern, a green color filter pattern, and a red color filter pattern are laminated on the first, second, and third semi-transparent plates, respectively.

5. The light emitting display device of claim 4, wherein the first insulating layer covers the first semi-transparent plate and the blue color filter pattern, and
wherein the second insulating layer covers the first insulating layer covering the first semi-transparent plate and the blue color filter pattern, and the second semi-transparent plate and the green color filter pattern.

6. The light emitting display device of claim 5, wherein each of the first and second insulating layers has a lower refractive index than a refractive index of each of the blue, green, and red color filter patterns.

7. The light emitting display device of claim 1, further comprising a third insulating layer formed between the light emitting diode and the first semi-transparent plate and arranged in the red, green, and blue subpixels.

8. The light emitting display device of claim 1, wherein the first electrode of each of the red, green, and blue subpixels includes a reflective layer.

9. The light emitting display device of claim 1, wherein each of the red, green, and blue subpixels further includes a reflective plate disposed below the first electrode, and
wherein the first electrode of each of the red, green, and blue subpixels is configured of a transparent electrode.

10. The light emitting display device of claim 1, wherein each of the first and second insulating layers includes at least one of Al2O3, SiO2, SiNx, monomer, and polyimide.

11. The light emitting display device of claim 1, wherein the second semi-transparent plate is positioned higher than the first semi-transparent plate by a thickness of the first insulating layer.

12. The light emitting display device of claim 1, wherein the third semi-transparent plate is positioned higher than the second semi-transparent plate by a thickness of the second insulating layer.
